(19) United States
(12) Patent Application Publication
(10) Pub. No.: US 2014/0028163 A1
(43) Pub. Date: Jan. 30, 2014

(54) HOUSING AND METHOD FOR MANUFACTURING THE SAME

(71) Applicants: Hon Hai Precision Industry Co., Ltd., New Taipei (TW); Fu Tai Hua Industry (Shenzhen) Co., Ltd., Shenzhen (CN)

(72) Inventor: WEI DENG, Shenzhen (CN)

(21) Appl. No.: 13/917,652

(22) Filed: Jun. 14, 2013

(30) Foreign Application Priority Data
Jul. 24, 2012 (CN) 2012102572519

(51) Int. Cl. H05K 5/02; B29C 45/14

(52) U.S. Cl. CPC H05K 5/02; B29C 45/14
USPC 312/223.1; 216/52

(57) ABSTRACT

A housing with a metal member is integrated with a plastic member to form a housing. The surface of the metal member carries a plurality of holes and a plurality of nano-depressions, both on the surface of the metal member and on the inner surfaces of each of the holes, which are produced by an electrochemical process. A depth, width, and diameter of each of the holes are controlled to be in preset ranges, and the resistance to bending and the tensile strength of the integrated metal plastic housing are very good. A method for manufacturing the housing is also provided.

### BACKGROUND

1. Technical Field

This disclosure relates to housings, particularly to a housing made of metal and plastic, and a method for manufacturing the housing.

2. Description of Related Art

Metals, such as aluminum alloy, magnesium alloy, or stainless steel alloy generally have excellent appearance and mechanical performance. Metals are applied for manufacturing housings of touch panel, mobile phone or other electronic devices. Smaller structures which need to be formed in a surface of the housings are usually machined by computer numerical control machine, which will spend a lot of time to machine the smaller structures. Integrated structures of metal and plastic are used in a wide range of industrial applications and fields in order to increase the processing efficiency of the housings. Generally, the metal and the plastic are joined together by adhesive. However, this method cannot supply a high-strength composite of metal and plastic.

Therefore, there is room for improvement in the art.

### BRIEF DESCRIPTION OF THE DRAWINGS

Many aspects of the disclosure can be better understood with reference to the following drawings. The components in the drawings are not necessarily drawn to scale, the emphasis instead being placed upon clearly illustrating the principles of the disclosure. Moreover, in the drawings, like reference numerals designate corresponding parts throughout the several views. Wherever possible, the same reference numerals are used throughout the drawings to refer to the same or like elements of an embodiment.

FIG. 1 is an isometric, assembled view of a first embodiment of a housing including a metal member.

FIG. 2 is a partial, cross-sectional view of the housing of FIG. 1 taken along line II-II.

FIG. 3 shows a scanning electron microscope (SEM) photograph of an adjoining plane of the housing of FIG. 1.

FIG. 4 is a flowchart of a method for manufacturing the housing of FIG. 1.

FIG. 5 is a photograph of the housing of FIG. 1 after being treated by laser.

FIG. 6 is a photograph of a second embodiment of a housing after being treated by laser.

FIG. 7 shows a scanning electron microscope (SEM) photograph of the metal member of the housing of FIG. 1 after being etched by an electrochemical process.

### DETAILED DESCRIPTION

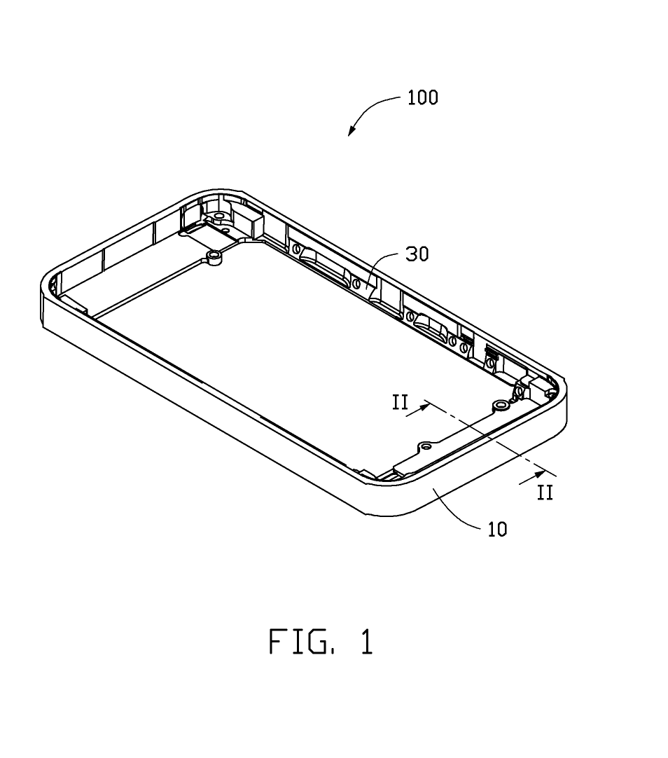

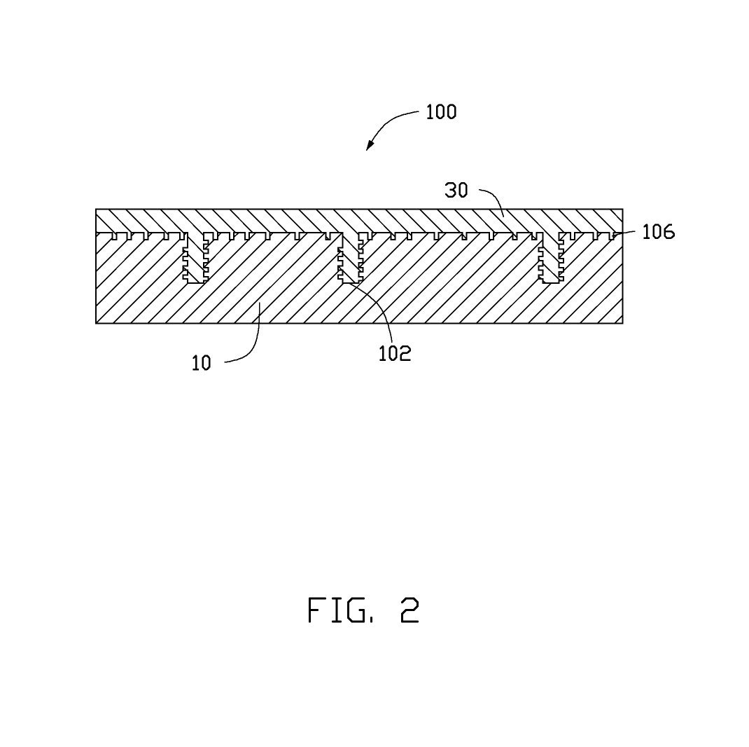

Referring to FIGS. 1 through 3, a first embodiment of a housing 100 includes a metal member 10 and a plastic member 30 integrated with the metal member 10. In the illustrated embodiment, the housing 100 is a mobile phone housing. In alternative embodiments, the housing 100 can be a housing used for touch panels, computers, or other electronic devices.

In the illustrated embodiment, the metal member 10 is substantially a rectangular frame. The metal member 10 defines a plurality of holes 102 in the inner surface of the metal member 10. The metal member 10 further forms a plurality of nano-depressions 106 in the inner surface of the metal member 10 and the inner surface of each of the holes 102, respectively, by an electrochemical process. The metal member 10 is made of aluminum alloy. In alternative embodiments, the metal member 10 can be made of magnesium alloy, stainless steel alloy, or other metal or metal alloys. The plastic material for the plastic member 30 can be selected from the group consisting of a composite of polyamide (PA), polyphenylene sulfide (PPS), polybutylene terephthalate (PBT), or polyethylene terephthalate (PET).

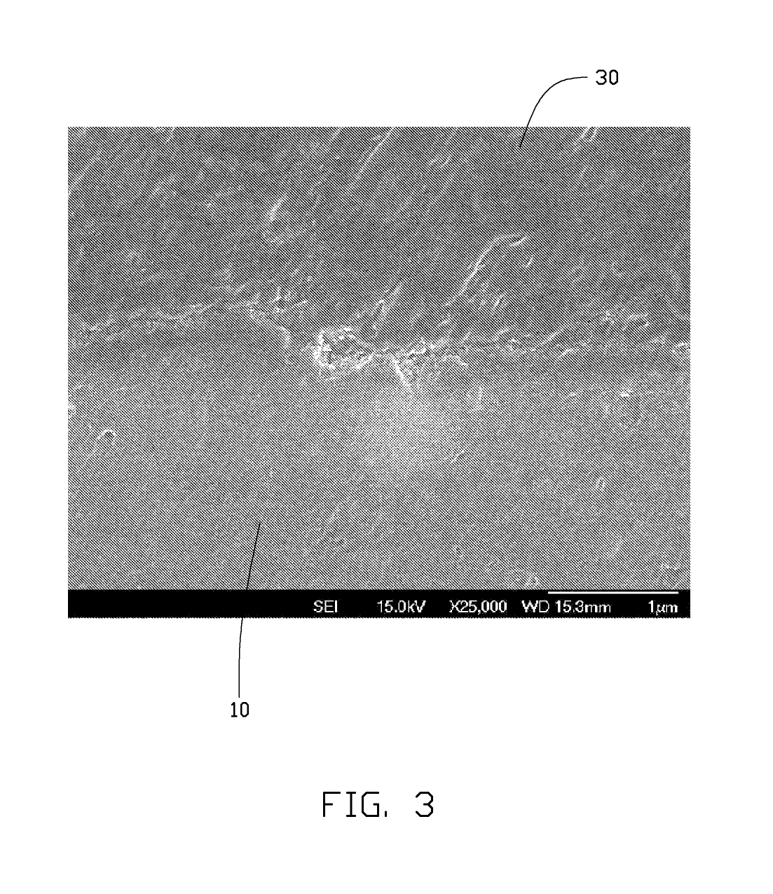

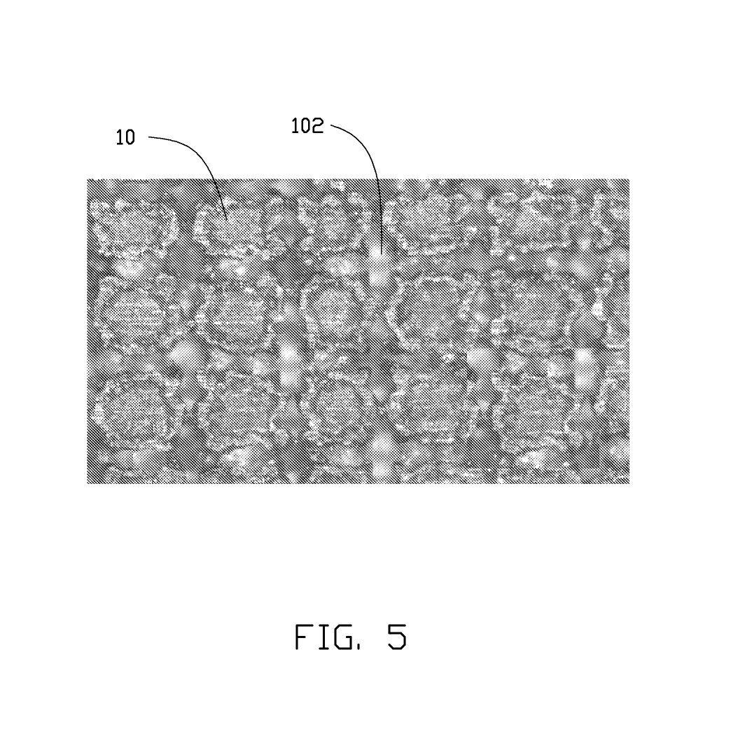

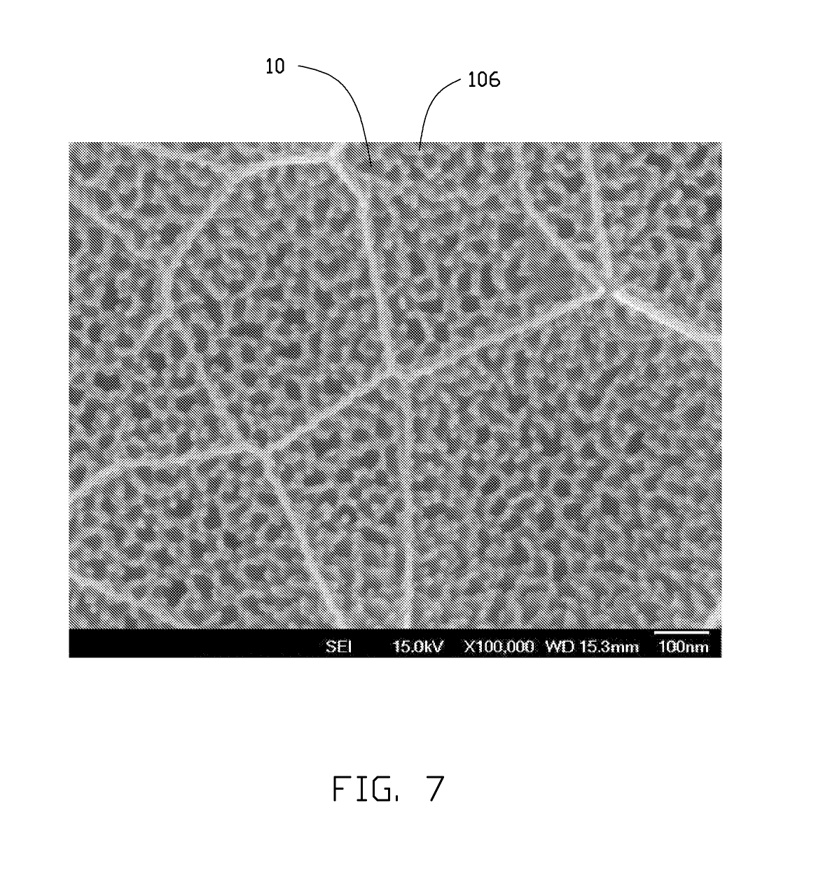

Referring to FIGS. 5 and 7, the holes 102 are connected together to form a plurality of grooves intersecting with each other (as shown in FIG. 5). A depth of each of the holes 102 is controlled to be in a range from about 27 μm to about 33 μm. A width of each of the holes 102 is controlled to be in a range from about 42 μm to about 50 μm. A diameter of each of the nano-depressions 106 is controlled to be in a range from about 30 nm to about 60 nm (as shown in FIG. 7). The housing 100 is formed by injection molding. The plastic member 30 is integrated with the inner surface of the metal member 10, and plastic material fills the holes 102 and the nano-depressions 106 (as shown in FIG. 3).

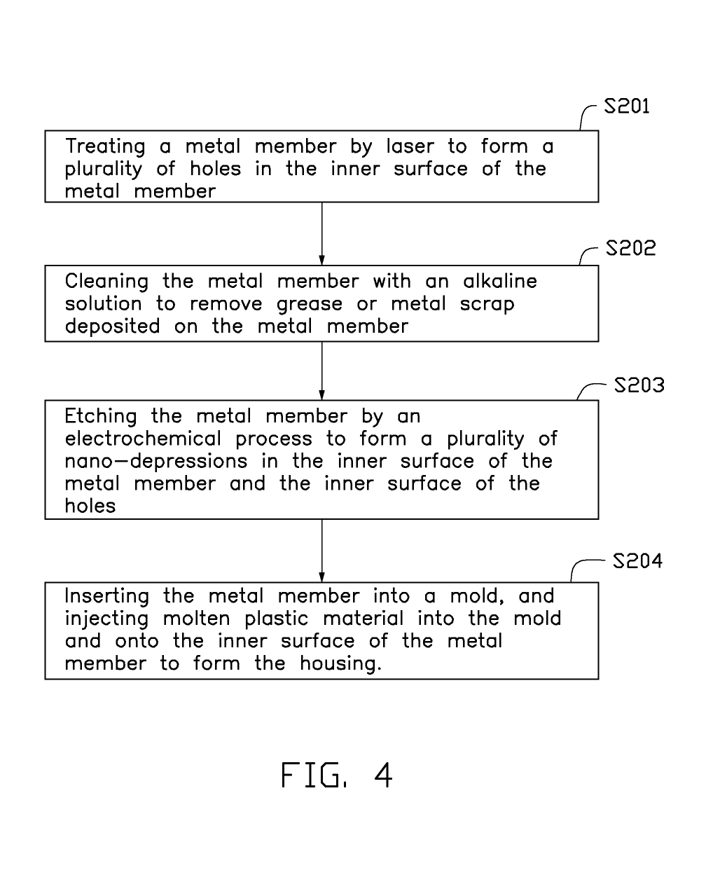

Referring to FIG. 4, a method for manufacturing the housing 100 of FIG. 1 is described as follows:

In step S201, the metal member 10 is treated by laser to form a plurality of holes 102 in the inner surface of the metal member 10. In the illustrated embodiment, the metal member 10 is made of aluminum alloy. The laser power is 25 Watts (W), the laser radiation frequency is 50 KHz, the laser beam diameter of the laser is 10 μm, and the laser scanning speed is 14 mm/s. A depth of each of the holes 102 is controlled to be in a range from about 27 μm to about 33 μm. A width of each of the holes 102 is controlled to be in a range from about 42 μm to about 50 μm. In alternative embodiments, the depth or width of each of the holes 102 can be changed by changing or adjusting the laser power, the laser radiation frequency, and the laser scanning speed.

In step S202, the metal member 10 is cleaned with an alkaline solution to remove grease or metal scraps deposited on the metal member 10. In the illustrated embodiment, the metal member 10 is immersed in a 5 percent by weight (5 wt %) sodium hydroxide solution. The metal member 10 is washed with water after removal from the sodium hydroxide solution.

In step S203, the metal member 10 is etched by an electrochemical process to form a plurality of nano-depressions 106 in the inner surface of the metal member 10 and the inner surface of the holes 102, respectively. An electrolyte may contain acetic acid, phosphoric acid, hydrochloric acid, or nitric acid to etch the metal member 10 to form the plurality of nano-depressions 106 in the inner surface of the metal member 10 and the inner surface of the holes 102. A diameter of each of the nano-depressions 106 is controlled to be in a range from about 30 nm to about 60 nm.

In step S204, the metal member 10 is inserted into a mold, and molten plastic material is injected into the mold and onto the inner surface of the metal member 10 to form the housing 100. In the illustrated embodiment, the plastic material is polyamide (PA), and the polyamide (PA) is a thermoplastic resin which crystallizes when it cools. The molten plastic material becomes partially embedded in the holes 102 and the nano-depressions 106, and bonds with the metal member 10. The plastic material for the plastic member 30 can be selected from the group consisting of a composite of polyamide (PA), polyphenylene sulfide (PPS), polybutylene terephthalate (PBT), or polyethylene terephthalate (PET).

In an alternative embodiment, step 202 can be omitted if the amounts of grease and metal scraps do not affect the etching of the metal member 10.

Samples of housings A and B manufactured by the present method are provided. Contrast samples of housings C, D, and E manufactured by injection molding are also provided. The contrast samples of housings C, D, and E were not treated by laser or etched by an electrochemical process. Investigation of the mechanical test results for the housings (A-E) are applied under a bending test and a split pulling test. The test results of the housings (A-E) are recorded in Table 1.

TABLE 1
Testing Results

| | Testing Items | | | |
|---|---|---|---|---|
| | Bending Test | | Split Pulling Test | |
| | | Deflection | | Deflection |
| Sample | Force (Kgf) | (mm) | Force (Kgf) | (mm) |
| A | 70.6 | 2.14 | >54.3 | 1.75 |
| B | 50.4 | 3.57 | >88.3 | 1.82 |
| C | 23.2 | 1.16 | 23.0 | 1.05 |
| D | 16.2 | 0.79 | 28.0 | 1.02 |
| E | 20.7 | 0.92 | 26.0 | 0.87 |

As shown in Table 1, resistance to bending and anti-tearing properties of the housings A and B are both better than the contrast samples for the housings B-E. Bonding force between the metal member 10 and the plastic member 30 is thus improved.

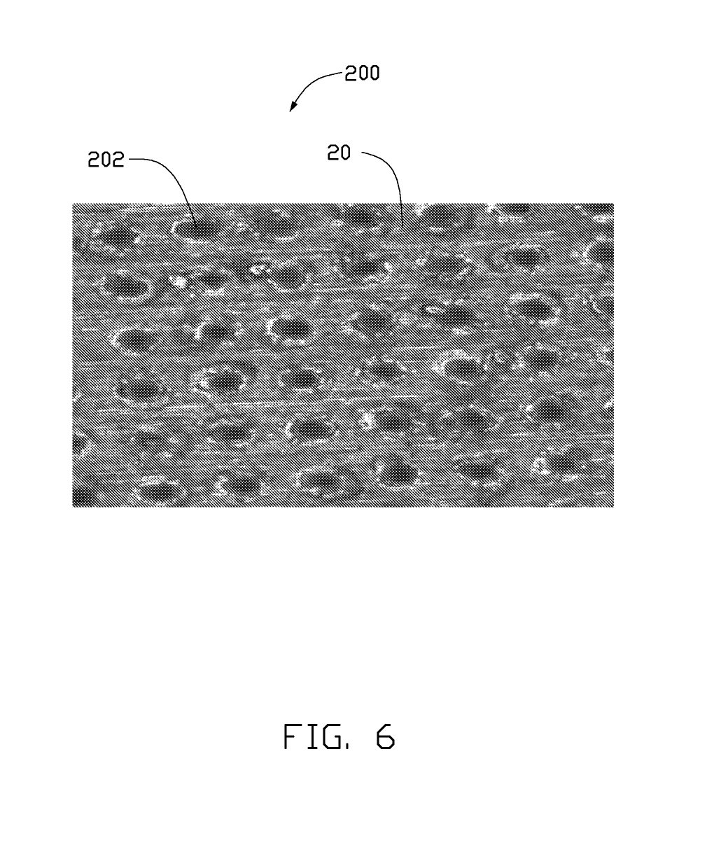

FIG. 6 shows a second embodiment of a housing 200. A method for manufacturing the housing 200 is similar to the method for manufacturing the housing 100, except that a laser scanning speed for the housing 200 is 14 mm/s, and a plurality of holes 202 defined in a metal member 20 of the housing 200 are circular blind cavities. A depth of each of the holes 202 is controlled to be in a range from about 50 μm to about 60 μm. A diameter of each of the holes 202 is controlled to be in a range from about 38 nm to about 46 nm.

The nano-depressions 106 have higher population density, which can improve the bonding force between the metal member 10 and the plastic member 30. In addition, the holes 102 are deeper and wider than the nano-depressions 106, which improves the resistance to tearing of the housing 100.

The present embodiments and their advantages will be understood from the foregoing description, and it will be apparent that various changes may be made thereto without departing from the spirit and scope of the embodiments or sacrificing all of its material advantages.

What is claimed is:

1. A housing, comprising:
a metal member, the metal member defining a plurality of holes by laser in a surface of the metal member and a plurality of nano-depressions in the surface of the metal member and an inner surface of each of the holes by an electrochemical process, respectively, wherein a depth of each of the holes is in a range from about 27 μm to about 33 μm, a width of each of the holes is in a range from about 42 μm to about 50 μm, and a diameter of each of the nano-depressions is in a range from about 30 nm to about 60 nm; and
a plastic member, the plastic member integrated with the surface of the metal member with the holes and the nano-depressions filled of plastic material.

2. The housing of claim 1, wherein the holes are connected together to form a plurality of stripe-shaped grooves intersected with each other.

3. The housing of claim 1, wherein the metal member is a rectangular frame, and the plastic member is integrated with the inner surface of the metal member.

4. The housing of claim 1, wherein the holes are circular blind cavities.

5. A method for manufacturing a housing, the method comprising:
treating a metal member by laser to form a plurality of holes in a surface of the metal member;
etching the metal member by an electrochemical process to form a plurality of nano-depressions in the surface of the metal member and the inner surface of the holes; and
inserting the metal member into a mold, and injecting molten plastic material into the mold and onto the surface of the metal member to form the housing.

6. The method of claim 5, further comprising of cleaning the metal member with an alkaline solution to remove greasy dirt or metal scraps deposited on the metal member before etching the metal member.

7. The method of claim 5, wherein the metal member is made of aluminum alloy, magnesium alloy, or stainless steel alloy.

8. The method of claim 5, wherein the plastic member is made of a plastic material selected from the group consisting of a composite of polyamide (PA), polyphenylene sulfide (PPS), polybutylene terephthalate (PBT), or polyethylene terephthalate (PET).

9. The method of claim 5, wherein the laser power is 25 Watts, the laser radiation frequency is 50 KHz, the laser beam diameter of the laser 10 is 10 μm, and the laser scanning speed is 14 mm/s.
